(19) United States
(12) Patent Application Publication
(10) Pub. No.: US 2009/0302464 A1
(43) Pub. Date: Dec. 10, 2009

(54) SEMICONDUCTOR DEVICE

(76) Inventors: Tomokatsu Nakagawa, Osaka (JP); Tatsuya Katoh, Osaka (JP); Satoru Kudose, Osaka (JP)

Correspondence Address: HARNESS, DICKEY & PIERCE, P.L.C., P.O. BOX 8910, RESTON, VA, 20195, US

(21) Appl. No.: 12/312,960

(22) PCT Filed: Nov. 27, 2007
(86) PCT No.: PCT/JP2007/072826

§ 371 Date: Jun. 2, 2009

(30) Foreign Application Priority Data
Dec. 4, 2006 (JP) 2006-=327480

(51) Int. Cl. H01L 23/12; H01L 23/48

(52) U.S. Cl. 257/737; 257/734; 257/E23.003; 257/E23.01

(57) ABSTRACT

A semiconductor device allowing for chip size reduction and thereby cost reduction without being restricted by a layout of bumps comprises a film substrate, an interposer substrate (3) made of silicon and mounted on the film substrate and a semiconductor element (2) mounted on the interposer substrate (3) in order to drive liquid crystals. The interposer substrate (3) includes a plurality of substrate projecting electrodes (5a, 5b, 5c) formed on its surface facing the semiconductor element (2), while the semiconductor element (2) includes a plurality of element projecting electrodes (4a, 4b, 4c) configured to be joined to the plurality of substrate projecting electrodes (5a, 5b, 5c), the plurality of element projecting electrodes (4a, 4b, 4c) being disposed throughout a surface of the semiconductor element (2).

### TECHNICAL FIELD

The present invention relates to a semiconductor device comprising: a film substrate; an interposer substrate on the film substrate, the interposer substrate being made of a semiconductor material such as silicon or the like; and a semiconductor element mounted on the interposer substrate, in order to drive liquid crystals.

### BACKGROUND ART

The number of transistors incorporated in Integrated Circuits (IC), as well as the number of circuits comprised inside the ICs, is increasing every year. Due to the recent progress made in high-definition liquid crystal panels, the number of driving circuits has been increasing in parallel to the number of display pixels. In order to provide this increasing number of driver circuits, it has become necessary either to increase the number of liquid crystal drivers mounted in the liquid crystal panel or to increase the number of driver circuits installed per liquid crystal driver. In recent years, it has been quite often to resort to the second solution, that is to increasing the number of driver circuits per liquid crystal driver, thereby avoiding increasing the number of liquid crystal drivers mounted in the liquid crystal panel.

IC chips of smaller sizes can be produced more efficiently to be lower in cost. As a result, in the case of a multi-output driver, it becomes necessary to use a finer pitch for pads in order to reduce the size of the chip. Further, the finer pitch of the pads of the IC chip requires inner leads of a film to have a finer pitch (the inner leads are the wiring connecting the liquid crystal driver and the film, which serves as the package of the driver).

FIG. 8 shows a schematic cross section view of a structure of a conventional semiconductor device 91. The semiconductor device 91 provides a printed substrate 80. The printed substrate 80 has a hole 85. A wiring pattern 84 is formed on a surface of the printed substrate 80.

The semiconductor device 91 provides an interposer substrate 93. A plurality of projecting electrodes 82 made of gold is provided on the interposer substrate 93, so as to be opposite to the wiring pattern 84 located on the surface of the printed substrate 80. The interposer substrate 93 is mounted on the printed substrate 80 through the projecting electrodes 82 and the wiring pattern 84.

A plurality of substrate projecting electrodes 95 made of gold is provided on the interposer substrate 93, so as to be opposite to the hole 85 located on the surface of the printed substrate 80.

A semiconductor element 92 is provided in the hole 85 of the printed substrate 80. A plurality of element projecting electrodes 94 made of gold is provided on a periphery of that surface of the semiconductor element 92 which faces the interposer substrate 93. The semiconductor element 92 is mounted on the interposer substrate 93 through the element projecting electrodes 94 and the substrate projecting electrodes 95. Gaps between the semiconductor element 92 and the printed substrate 80 and between the interposer substrate 93, the printed substrate 80 and the semiconductor element 92, are sealed with the sealing resin 86.

### Citation List

Patent Literature 1

Japanese Patent Application Publication Tokukai No. 2004-193161 (Publication Date: Jul. 8, 2004)

### SUMMARY OF INVENTION

However, the aforementioned conventional structure has the following problem. Namely, since the element projecting electrodes 94 used for mounting the semiconductor element 92 on the interposer substrate 93 are located on the periphery on the surface of the semiconductor element 92, the layout of the element projecting electrodes 94 restricts size reduction of the semiconductor element 92, thereby making it difficult to lower the costs.

In view of the aforementioned problem, an object of the present invention is to provide a semiconductor device allowing for a reduction of the size of the chip and lowering of the costs, without being restricted by layout of the bumps.

In order to attain the object, a semiconductor device according to the present invention includes a film substrate, an interposer substrate made of silicon and mounted on the film substrate, and a semiconductor element mounted on the interposer substrate in order to drive the display elements, wherein the interposer substrate includes a plurality of substrate projecting electrodes formed on one surface thereof facing the semiconductor element, the semiconductor element includes a plurality of element projecting electrodes configured to be joined to the substrate projecting electrodes correspondingly, wherein: the plurality of element projecting electrodes is disposed throughout a surface of the semiconductor element.

With the feature that the plurality of element projecting electrodes is disposed throughout the surface of the semiconductor element, the substrate projecting electrodes used to extract a signal from a wiring pattern located on the interposer substrate can be positioned with a higher degree of freedom. As a result, it is possible to reduce the size of the chip and to lower the costs, without being restricted by the layout of the bumps.

The semiconductor device according to the present invention is preferably configured such that the plurality of element projecting electrodes is disposed in staggered configuration.

This configuration in which the plurality of element projecting electrodes is disposed in a staggered configuration, stress applied on each junction of the plurality of element projecting electrodes and the plurality of substrate projecting electrodes can be spread uniformly, thus increasing reliability of the junctions.

The semiconductor device according to the present invention is preferably configured such that the plurality of element projecting electrodes is disposed in linear symmetry.

With this configuration in which the plurality of element projecting electrodes is disposed in linear symmetry, stress applied on each of the junctions of the element projecting electrodes and the substrate projecting electrodes can be spread uniformly, thus increasing the reliability of the junctions.

The semiconductor device according to the present invention is preferably configured such that the plurality of element projecting electrodes is disposed so that the number of the element projecting electrodes jointed with the substrate projecting electrodes is reduced when the substrate and the semiconductor element are joined with one of them rotated 180 degrees.

With this configuration, when attempting to check the state of the junction between the element projecting electrode and the substrate projecting electrode by detaching the semiconductor element from the interposer substrate, it is possible to easily check the state of the junction by intentionally reducing the strength of the junction between the element projecting electrode and the substrate projecting electrode.

The semiconductor device according to the present invention preferably comprises: element dummy bumps outside of where the plurality of element projecting electrodes is provided, the element dummy bumps protecting junctions between the element projecting electrodes and the substrate projecting electrodes; and substrate dummy bumps outside of where the plurality of substrate projecting electrodes is provided, the substrate dummy bumps being configured to be joined to the element dummy bumps correspondingly.

With this configuration, it is possible to protect the outer bumps, which most likely receive stress to come off.

The semiconductor device according to the present invention preferably comprises: inner-side element dummy bumps inside of where the plurality of element projecting electrodes is provided, the inner-side element dummy bumps protecting junctions between the element projecting electrodes and the substrate projecting electrodes; and inner-side substrate dummy bumps inside of where the plurality of substrate projecting electrodes is provided, the inner-side substrate dummy bumps being configured to be joined to the inner-side element dummy bumps.

With this configuration, it is possible to protect the inner-side bumps, which likely receive stress from invasion, thermal swelling, etc. of a sealing resin, thereby to come off.

The semiconductor device according to the present invention preferably comprises: element dummy bumps respectively on outside and inside of where the plurality of element projecting electrodes is provided, the element dummy bumps protecting junctions between the element projecting electrodes and the substrate projecting electrodes; and a wiring pattern for electrically connecting the element dummy bump provided outside and the element dummy bump provided inside.

With this configuration, it is possible, by checking a resistance of the wiring pattern electrically linking an element dummy bump provided outside and an element dummy bump provided on inside, to check the state of the junction between the element projecting electrodes and the substrate junction electrodes in a pseudo manner.

The semiconductor device according to the present invention preferably comprises: an unmounted projecting electrode on the semiconductor element, the unmounted projecting electrode having a gap with the interposer substrate.

With this configuration, it is possible to confirm the height and size of the element projecting electrodes and of the substrate projecting electrodes by emitting an infrared laser through the interposer substrate towards the unmounted projecting electrode, and detecting reflected light.

The semiconductor device according to the present invention is preferably configured such that the unmounted projecting electrode is provided in a part of a region located above a metal wiring pattern formed on the semiconductor element.

With this configuration, it is possible to easily confirm the element projecting electrodes and the substrate projecting electrodes in size and height by detecting, on one hand, the reflection of the laser light reflected by the unmounted projecting electrodes disposed in a part of the region located above the metal wiring pattern and, on the other hand, the laser light reflected by the remaining part of the region located above the metal wiring pattern.

The semiconductor device related to the present invention, as described above, allows for a greater degree of freedom in the layout of the substrate projecting electrodes used for drawing out the signal from the wiring pattern located on the interposer substrate, since a plurality of element projecting electrodes is disposed throughout the surface of the semiconductor element. As a result, without being restricted by the disposition of the bumps, the semiconductor device according to the present invention allows for chip size reduction and cost reduction.

### BRIEF DESCRIPTION OF DRAWINGS

FIG. 1 is a cross-sectional view of a structure of a semiconductor device in accordance with an embodiment.

FIG. 2 is a plan view of a configuration of mounting surfaces of a semiconductor element and of an interposer substrate provided on the semiconductor device, where (a) shows the mounting surface of the semiconductor element and (b) shows the mounting surface of the interposer substrate.

FIG. 3 is a plan view of a layout of element projecting electrodes provided on the semiconductor element and of the substrate projecting electrodes provided on the interposer substrate, where (a) shows the layout of the element projecting electrodes and (b) shows the layout of the substrate projecting electrodes.

FIG. 4 is a plan view of a layout of another substrate projecting electrodes provided on the interposer substrate and of the projecting electrodes provided on the interposer substrate in order to mount it on the film substrate, where (a) shows the layout of the other substrate projecting electrodes and (b) shows the layout of the projecting electrodes.

FIG. 5 is an explanatory view for explaining that the number of connected bumps is reduced when the substrate and the semiconductor element are joined with one of them rotated 180 degrees.

FIG. 6 is an explanatory plan view for explaining the unmounted projecting electrodes provided on the semiconductor element, and explaining the metal-free region provided on the interposer substrate, where (a) explains the unmounted projecting electrodes and (b) explains the metal-free region.

FIG. 7 is a plan view of a layout of the unmounted projecting electrodes.

FIG. 8 is a schematic cross section view of a structure of a conventional semiconductor device.

### REFERENCE LIST

1 Semiconductor device
2 Semiconductor element
3 Interposer substrate
4a, 4b, 4c Element projecting electrodes
5a, 5b, 5c Substrate projecting electrodes
6a Element dummy bump
6b Substrate dummy bump
7a Inner-side element dummy bump
7b Inner-side substrate dummy bump
8a Unmounted projecting electrode
8b Unmounted projecting electrode
10 Film substrate
11 Dummy bump
12 Projecting electrode
13 Metal-free region
14 Wiring pattern
15 Hole
16 Sealing resin

### DESCRIPTION OF THE PREFERRED EMBODIMENTS

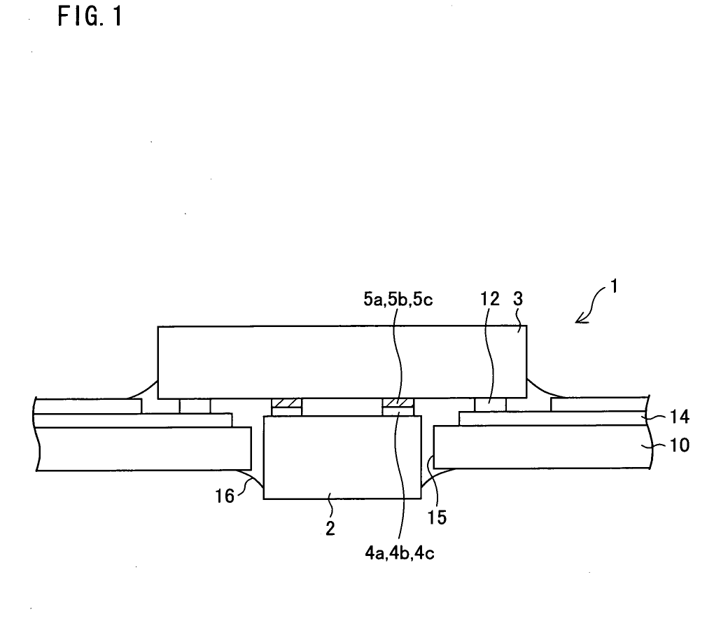

One embodiment of the present invention is described below with reference to the attached drawings (FIGS. 1 to 7). FIG. 1 is a schematic cross-sectional view of a structure of the semiconductor device 1 in accordance with the embodiment of the present embodiment. The semiconductor device 1 includes a film substrate 10. The film substrate 10 has a hole 15. On a surface of the film substrate 10, a wiring pattern 14 is formed.

The interposer substrate 3 is provided on the semiconductor device 1. On that surface of the interposer substrate 3 which faces to the film substrate 10, a plurality of projecting electrodes 12 made of gold is provided, so as to be opposite to the wiring pattern 14.

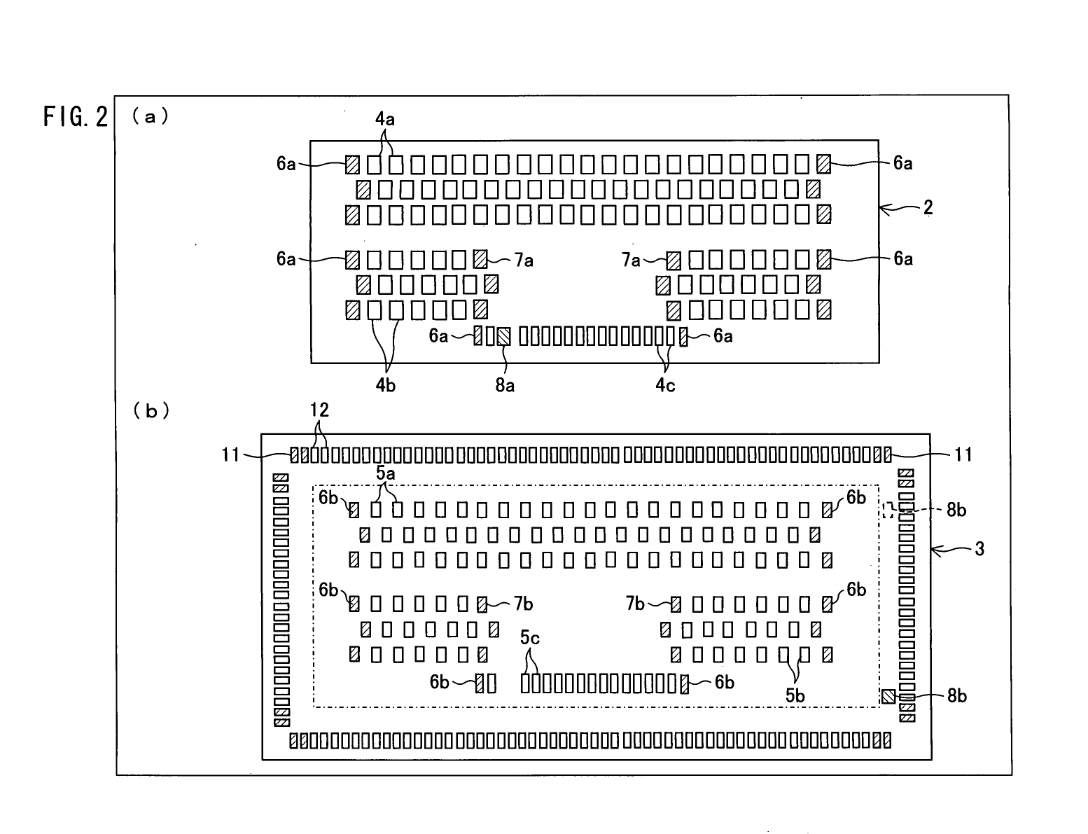

FIG. 2(a) is a plan view of a configuration of a mounting surface of the semiconductor element 2 provided on the semiconductor device 1. FIG. 2(b) is a plan view of a configuration of a mounting surface of the interposer substrate 3 provided on the semiconductor 1.

Plural projecting electrodes 12 are provided along each of the four edges on the mounting surface of the rectangular interposer substrate 3. On both ends of the rows of the plural projecting electrodes 12 provided along each edge, dummy bumps 11 are provided. The interposer substrate 3 is mounted on the film substrate 10 with the projecting electrodes 12 and the wiring pattern 14 sandwiched therebetween.

The rectangular substrate projecting electrodes 5a, 5b, 5c, made of gold, are provided on the interposer substrate 3 so as to face the hole 15 of the film substrate 10.

The substrate projecting electrodes 5a are disposed on the mounting surface of the interposer substrate 3, from one short edge towards the other short edge, in three rows in a staggered configuration. Substrate dummy bumps 6b are provided on both ends of each row of substrate projecting electrodes 5a.

The substrate projecting electrodes 5b are disposed on the mounting surface of the interposer substrate 3, from one short edge towards the center and from the other short edge towards the center, in three rows in a staggered configuration. The substrate projecting electrodes 5b are sandwiched between substrate dummy bumps 6b and inner-side substrate dummy bumps 7b. The substrate dummy bumps 6b are provided one end of the row of the substrate projecting electrodes 5b, which end is closer to either the one short edge or the other short edge of the interposer substrate 3, whereas the inner-side substrate dummy bumps 7b are provided the inner side of the substrate projecting electrodes 5b. The substrate projecting electrodes 5a and 5b are provided in order to receive the signal outputted by the semiconductor element 2 and to deliver the signal to the wiring pattern 14 of the film substrate 10.

On the mounting surface of the interposer substrate 3, a plurality of substrate projecting electrodes 5c, configured to deliver the signal to be inputted in the semiconductor element 2, is provided in one row. On both ends of the row of substrate projecting electrodes 5c, substrate dummy bumps 6b are provided.

Inside the hole 15 of the film substrate 10, the semiconductor element 2 is provided. Throughout that surface of the semiconductor element 2 which faces the interposer substrate 3, a plurality of element projecting electrodes 4a, 4b, 4c made of gold is provided.

The element projecting electrodes 4a and 4b are provided in order to deliver to the interposer substrate 3 the signal outputted by the semiconductor element 2, while the signal from the interposer substrate 3 is supplied to the semiconductor element 2 by the element projecting electrodes 4c. The element projecting electrodes 4a are disposed in three rows from one short edge of the mounting surface of the semiconductor element 2 to the other short edge. Element dummy bumps 6a are provided on both ends of each row of the element projecting electrodes 4a. The element projecting electrodes 4b are disposed in three rows from both short edges of the mounting surface towards the center. Element dummy bumps 6a are provided on the outer end of each row of the element projecting electrodes 4b, while inner-side element dummy bumps 7a are provided on the inner end of each row. Element dummy bumps 6a are provided on both ends of each row of the element projecting electrodes 4c.

The semiconductor element 2 is mounted on the interposer substrate 3 through the element projecting electrodes 4a, 4b, 4c, the element dummy bumps 6a, and the inner-side element dummy bumps 7a, as well as through the substrate projecting electrodes 5a, 5b, 5c, the element dummy bumps 6b, and the inner-side element dummy bumps 7b. The sealing resin 16 seals a gap between the semiconductor element 2 and the film substrate 10, as well as a gap between the interposer substrate 3 and the film substrate 10 and a gap between the interposer substrate 3 and the semiconductor element 2.

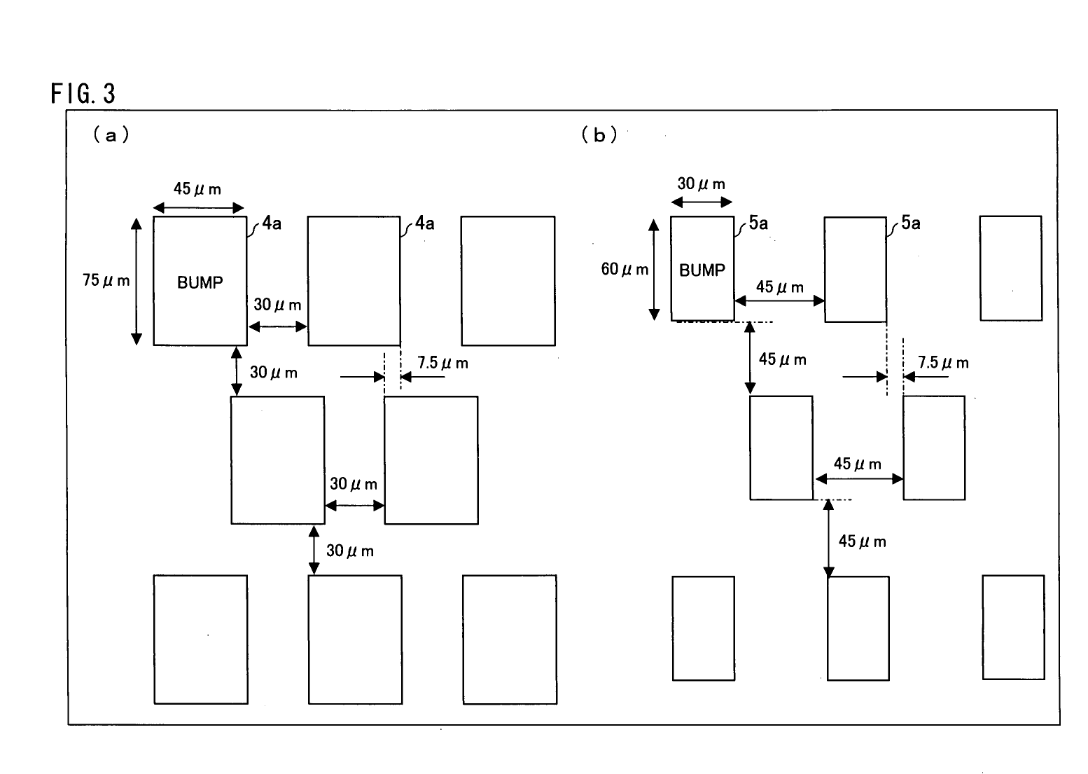

FIG. 3(a) is a plan view of a layout of the element projecting electrodes 4a provided on the semiconductor element 2, while FIG. 3(b) is a plan view of a layout of the substrate projecting electrode 5a provided on the interposer substrate 3. Each element projecting electrode 4a is for example rectangular, 75 μm long and 45 μm wide. Adjoining element projecting electrodes 4a in the same row are disposed with 30 μm intervals. Further, each row of the element projecting electrodes 4a is distanced from each other by 30 μm. The element projecting electrodes 4a in one row overlaps the corresponding element projecting electrodes 4a in the adjoining row by 7.5 μm. Each substrate projecting electrode 5a is for example rectangular, 60 μm long and 30 μm wide. Adjoining substrate projecting electrodes 5a in the same row are disposed with 45 μm intervals. Further, each row of the substrate projecting electrodes 5a is distanced by 45 μm. The substrate projecting electrodes 5a of one row are shifted from the corresponding substrate projecting electrodes 5a of the adjoining row by 7.5 μm.

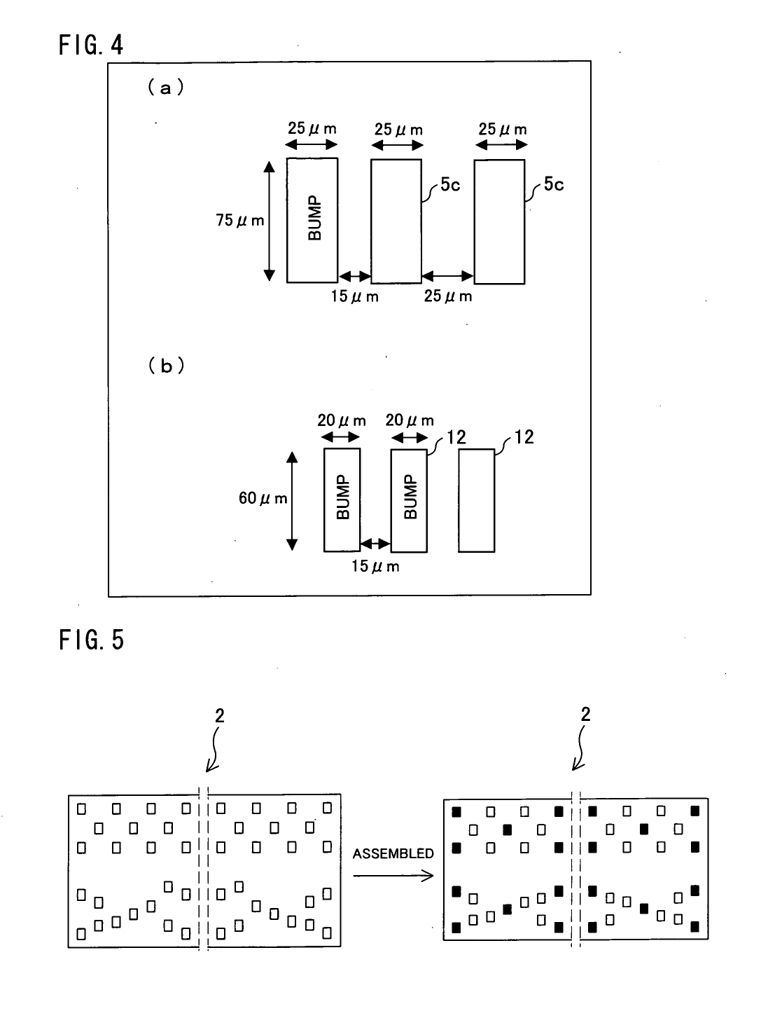

FIG. 4(a) is a plan view of a layout of the substrate projecting electrodes 5c provided on the interposer substrate 3, while FIG. 4(b) is a plan view of a layout of the projecting electrodes 12 provided on the interposer substrate 3 in order to mount the interposer substrate 3 on the film substrate 10. Each substrate projecting electrode 5c is for example rectangular, 75 μm long and 25 μm wide, and adjoining substrate projecting electrodes 5c are disposed with 15 μm or 25 μm intervals between each other. Each projecting electrode 12 is for example rectangular, 60 μm long and 20 μm wide, and adjoining projecting electrodes 12 are disposed with 15 μm intervals between each other.

Since the element projecting electrodes 4a, 4b and 4c are disposed throughout the surface of the semiconductor element 2, it is possible to extract the signal passing through the wiring pattern of the interposer substrate 3. The bumps may therefore be positioned with a higher degree of freedom. As a result, it is possible, without being restricted by the layout of the bumps, to reduce the size of the chip and thus to lower the costs.

Further, since the element projecting electrodes 4a and 4b are disposed in a staggered configuration, the stress on each of the junction of the element projecting electrodes and the substrate projecting electrodes can be uniformly spread.

Furthermore, the element projecting electrodes 4a, 4b and 4c are disposed periodically throughout the mounted surface of the semiconductor element 2. The element projecting electrodes 4a, 4b and 4c are provided in linear symmetry. As shown in FIG. 5, the linear symmetry layout of the element projecting electrodes 4a, 4b and 4c reduces the number of the element projecting electrodes 4a, 4b and 4c jointed with the substrate projecting electrodes 5a, 5b and 5c (as indicated by black rectangles), in case the substrate and the semiconductor element are joined with one of them rotated 180 degrees. Accordingly, when it becomes necessary to check a state of the junction by detaching the semiconductor element 2 from the interposer substrate 3, this configuration can intentionally reduce a strength of the junction between the semiconductor element 2 and the interposer substrate 3, thus making it possible to detach easily the semiconductor element 2 from the interposer substrate 3. This, in turn, makes it possible to check easily the state of the junction. It is also acceptable to dispose the element projecting electrodes 4a, 4b, 4c so as to reduce the number of joint bumps when the semiconductor element 2 is joined to the interposer substrate 3 by shifting horizontally or vertically the position of the semiconductor element 2.

Because the element dummy bumps 6a and inner-side element dummy bumps 7a are provided in such a manner that a row of the element dummy bumps 6a which do not contribute to the operation of the semiconductor element 2 is provided on the outer side of the short edge of the semiconductor element 2, the element dummy bumps 6a are provided on both ends of the row of the element projecting electrodes 4c, and the inner-side element dummy bumps 7a are provided on the inner side of the element projecting electrodes 4b, it is possible to protect bumps that are provided on edges and most likely receive stress to come off.

By connecting through a wiring pattern the element dummy bumps 6a located respectively at one end and the other end of the mounting surface of the semiconductor element 2 and checking a resistance of the wiring pattern, it is possible to check the state of the junction between the element projecting electrodes 4a, 4b, 4c and the substrate projecting electrodes 5a, 5b, 5c in a pseudo manner.

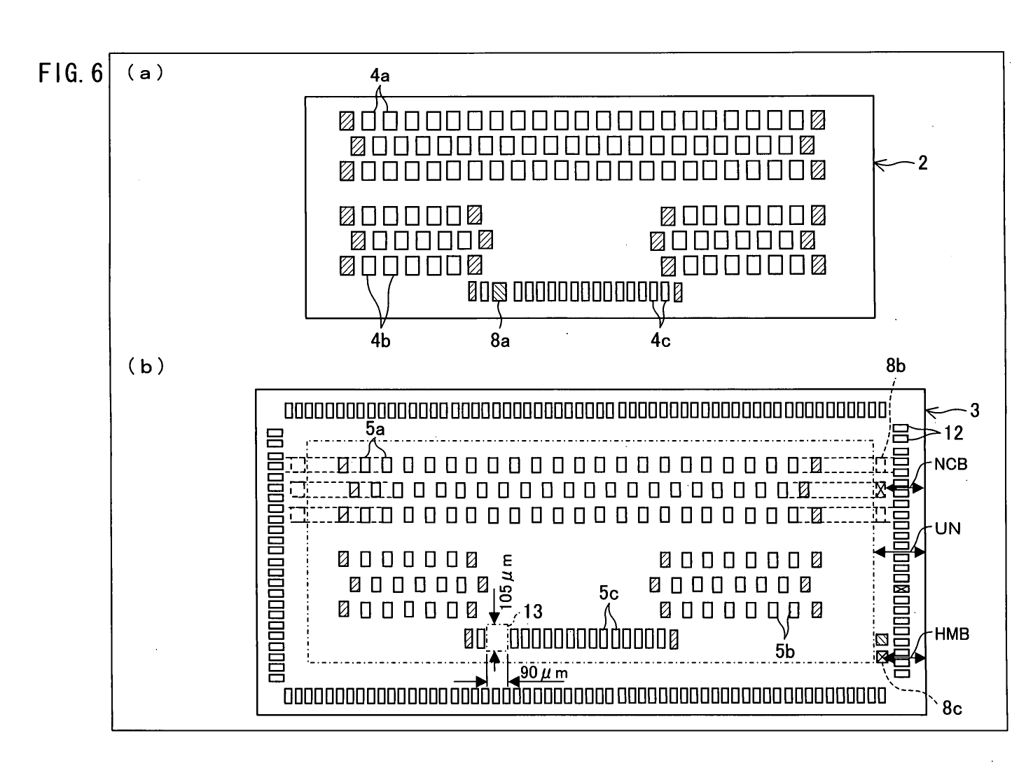

FIG. 6(a) is an explanatory plan view of unmounted projecting electrodes 8a provided on the semiconductor element 2, while FIG. 6(b) is an explanatory plan view of a metal-free region provided on the interposer substrate 3.

The unmounted projecting electrode 8a is provided between one element projecting electrode 4c and another element projecting electrode 4c. A 105 μm long and 90 μm wide metal-free region 13, prohibiting formation of metal wirings, is provided at a location corresponding to the unmounted projecting electrode 8a on the interposer substrate 3. The unmounted projecting electrode 8a is provided so as to maintain a gap with the interposer substrate 3 when the element projecting electrodes 4a, 4b, 4c and the substrate projecting electrodes 5a, 5b, 5c are jointed.

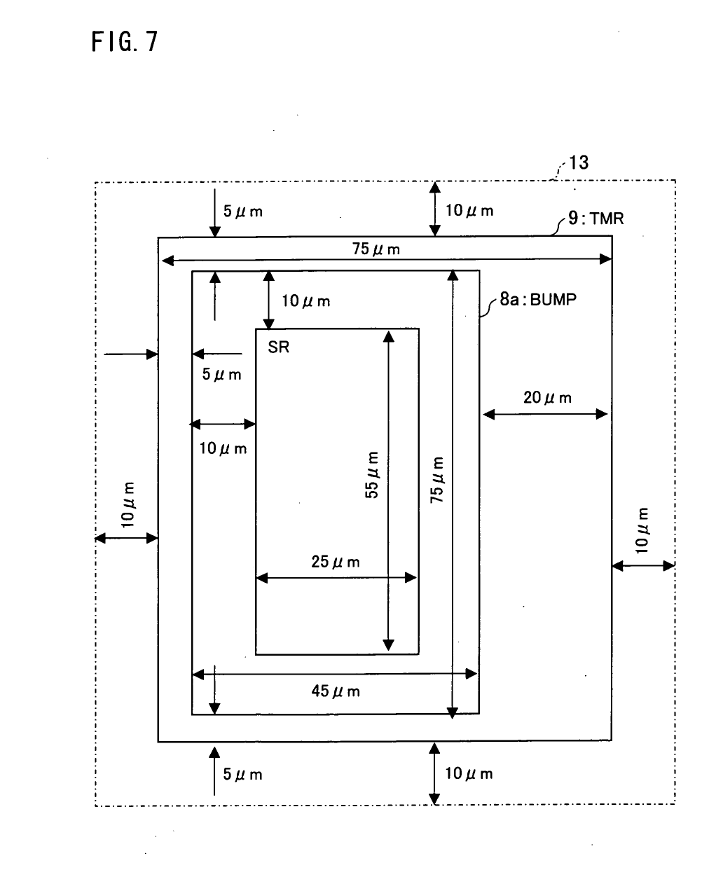

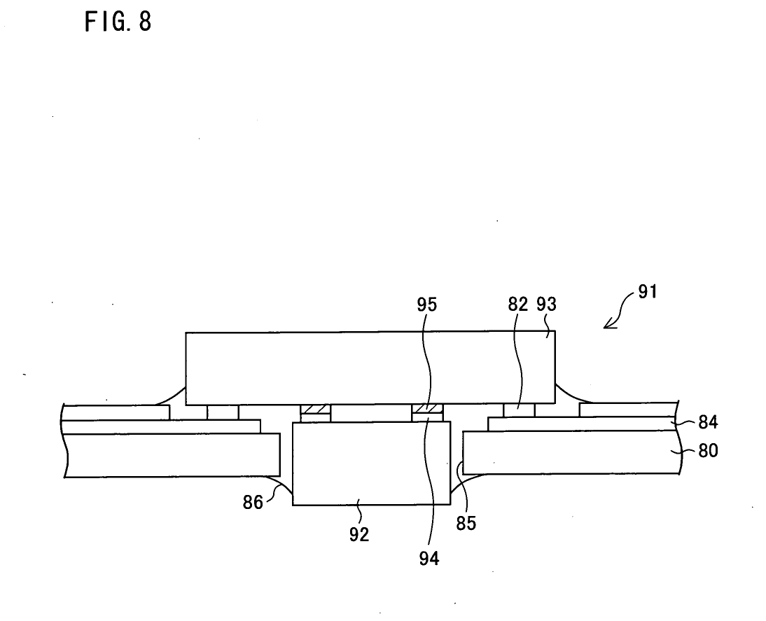

FIG. 7 is a plan view of a layout of the unmounted projecting electrode 8a. The unmounted projecting electrode 8a is provided on a region located between the element projecting electrodes 4c, on the basis of one per chip. The unmounted projecting electrode 8a has an outline shape of a rectangular frame for example 75 μm long and 45 μm wide; the width of each side of the frame is 10 μm. The unmounted projecting electrode 8a is provided on top of the metal wiring pattern 9. The unmounted projecting electrode 8a is disposed 5 μm away from three of edges of the metal wiring pattern 9, and 20 μm away from the remaining edge. When viewing in a direction vertical to the surface of the semiconductor element 2, the metal-free region 13 is positioned so as to cover the metal wiring pattern 9, and each of edges of the metal-free region 13 is positioned 10 μm away from a corresponding edge of the metal wiring pattern 9.

Between the semiconductor element 2 and the projecting electrodes 12 located on the interposer substrate 3, unmounted projecting electrodes 8b are provided in an extended line from a single row of the substrate projecting electrodes 5a. A distance UN, that is the distance between the short edge of the interposer substrate 3 and the short edge of the semiconductor element 2, and a distance NCB, that is the distance between the unmounted projecting electrodes 8b and the short edge of the interposer substrate 3, are related as follows:

NCB=UN−30 μm

A pad design thereof is identical to the pad design of the substrate projecting electrodes 5a shown in FIG. 3(b).

Between the semiconductor element 2 and the projecting electrodes 12 located on the interposer substrate 3, unmounted projecting electrodes 8c are provided. A distance HNB, that is the distance between a center of the unmounted projecting electrodes 8c and the short edge of the interposer substrate 3, and the distance UN are related as follows:

HNB=UN−42.5 μm

A pad design of the unmounted projecting electrodes 8c conforms to the following pattern: MR (metal wiring) is a 65 μm-sided square, SR (Silox) is a 35 μm-sided square, B (Au bump size) is a 55 μm-sided square, where all squares share the same center. Inside the SR square shown on FIG. 7, the metal and the bump are in direct contact, while outside the square, an insulating layer is provided between the metal wiring and the bump.

With such a configuration in which an 20 μm-wide offset region is provided to the unmounted projecting electrode 8a on the metal pattern 9 as shown in FIG. 7, it is possible to check the bumps in size and height by emitting an infrared laser through the silicon-made interposer substrate 3 to the semiconductor element 2, and detecting laser light reflected by the unmounted projecting electrode 8a and laser light reflected by the 20 μm-wide offset region of the metal wiring pattern 9.

The present invention is not limited to the above-described embodiment, and various modifications are possible within the scope of the claims. Namely, embodiments realized by combining technical means appropriately modified within the scope of the claims are also encompassed within the technical scope of the present invention. For example, the element projecting electrodes and substrate projecting electrodes make have a square shape.

### INDUSTRIAL APPLICABILITY

The present invention is applicable to a semiconductor device comprising a film substrate, an interposer substrate mounted on the film substrate and made of silicon, and a semiconductor element mounted on the interposer substrate in order to drive liquid crystals.

1. A semiconductor device including a film substrate, an interposer substrate made of silicon and mounted on the film substrate, and a semiconductor element mounted on the interposer substrate in order to drive the display elements, wherein the interposer substrate includes a plurality of substrate projecting electrodes formed on one surface thereof facing the semiconductor element, the semiconductor element includes a plurality of element projecting electrodes configured to be joined to the substrate projecting electrodes correspondingly, wherein:
the plurality of element projecting electrodes is disposed throughout a surface of the semiconductor element.

2. The semiconductor device according to claim 1, wherein the plurality of element projecting electrodes is disposed in staggered configuration.

3. The semiconductor device according to claim 1, wherein the plurality of element projecting electrodes is disposed in linear symmetry.

4. The semiconductor device according to claim 1, wherein the plurality of element projecting electrodes is disposed so that the number of the element projecting electrodes jointed with the substrate projecting electrodes is reduced when the substrate and the semiconductor element are joined with one of them rotated 180 degrees.

5. The semiconductor device according to claim 1, comprising:
element dummy bumps outside of where the plurality of element projecting electrodes is provided, the element dummy bumps protecting junctions between the element projecting electrodes and the substrate projecting electrodes; and
substrate dummy bumps outside of where the plurality of substrate projecting electrodes is provided, the substrate dummy bumps being configured to be joined to the element dummy bumps correspondingly.

6. The semiconductor device according to claim 1, comprising:
inner-side element dummy bumps inside of where the plurality of element projecting electrodes is provided, the inner-side element dummy bumps protecting junctions between the element projecting electrodes and the substrate projecting electrodes; and
inner-side substrate dummy bumps inside of where the plurality of substrate projecting electrodes is provided, the inner-side substrate dummy bumps being configured to be joined to the inner-side element dummy bumps.

7. The semiconductor device according to claim 1, comprising:
element dummy bumps respectively on outside and inside of where the plurality of element projecting electrodes is provided, the element dummy bumps protecting junctions between the element projecting electrodes and the substrate projecting electrodes; and
a wiring pattern for electrically connecting an element dummy bump provided outside and an element dummy bump provided inside.

8. The semiconductor device according to claim 1, comprising:
an unmounted projecting electrode on the semiconductor element, the unmounted projecting electrode having a gap with the interposer substrate.

9. The semiconductor device according to claim 1, wherein the unmounted projecting electrode is provided in a part of a region located above a metal wiring pattern formed on the semiconductor element.
